(19) United States
(12) Patent Application Publication
(10) Pub. No.: US 2026/0005202 A1
(43) Pub. Date: Jan. 1, 2026

(54) SEMICONDUCTOR PACKAGE HAVING SIDE PROTECTIONS AND METHOD OF MAKING THE SAME

(71) Applicant: ALPHA AND OMEGA SEMICONDUCTOR INTERNATIONAL LP, TORONTO (CA)

(72) Inventors: Yan Xun Xue, Los Gatos, CA (US); Long-Ching Wang, Cupertino, CA (US); Zhiqiang Niu, Santa Clara, CA (US); Chunya Wen, Santa Clara, CA (US)

(73) Assignee: ALPHA AND OMEGA SEMICONDUCTOR INTERNATIONAL LP, TORONTO (CA)

(21) Appl. No.: 18/759,365

(22) Filed: Jun. 28, 2024

(51) Int. Cl. H01L 25/07; H01L 21/304; H01L 23/00; H01L 23/31

(52) U.S. Cl. CPC H01L 25/072; H01L 21/304; H01L 23/3107; H01L 24/05; H01L 24/96; H01L 24/97; H01L 2224/05567; H01L 2224/05638; H01L 2224/96; H01L 2224/97; H01L 2924/13091

(57) ABSTRACT

A semiconductor package comprises a semiconductor substrate, a plurality of contact pads, a plated metal layer, and a molding encapsulation. The molding encapsulation directly contacts an entirety of each side surface of a plurality of side surfaces of the semiconductor substrate, and an entirety of each side surface of a plurality of side surfaces of the plated metal layer. A method comprises the steps of providing a semiconductor device wafer; applying a first thinning process; applying a dicing process; attaching a panel; forming a first molding encapsulation; applying a second thinning process, forming a plurality of plated metal sections, removing the panel, and applying a singulation process.

### FIELD OF THE INVENTION

This invention relates generally to a semiconductor package having side protections and a method of making a plurality of semiconductor packages. More particularly, the present invention relates to a semiconductor package, having a semiconductor substrate with a thickness in a range from 15 microns to 35 microns.

### BACKGROUND OF THE INVENTION

Process control monitor (PCM) products contains two double diffused metal oxide semiconductor field effect transistors (DMOSFETs). An electrical current flows into the PCM product, through a first DMOSFET, a common drain, a second DMOSFET, and then out of the PCM product. To reduce resistance, a thin substrate and a thick plated metal layer are required. Convention manufacturing process of PCM product uses a carrier to support a wafer during a grinding process and a metallization process, resulting in higher manufacturing cost.

The present disclosure uses a panel to support a wafer during a grinding process and a metallization process, resulting in lower manufacturing cost.

The semiconductor package comprises a molding encapsulation providing side protections, optional top protections, and optional bottom protections.

### SUMMARY OF THE INVENTION

A semiconductor package comprises a semiconductor substrate, a plurality of contact pads, a plated metal layer, and a molding encapsulation. The molding encapsulation directly contacts an entirety of each side surface of a plurality of side surfaces of the semiconductor substrate, and an entirety of each side surface of a plurality of side surfaces of the plated metal layer.

A method for fabricating a plurality of semiconductor packages is disclosed. The method comprises the steps of providing a semiconductor device wafer; applying a first thinning process; applying a dicing process; attaching a panel; forming a molding encapsulation; applying a second thinning process, forming a plurality of plated metal sections, removing the panel, and applying a singulation process.

### BRIEF DESCRIPTION OF THE DRAWINGS

FIGS. 1A, 1B, 1C, and 1D show a respective cross-sectional view of four semiconductor packages in examples of the present disclosure.

FIG. 2 is a flowchart of a process to develop a plurality of semiconductor packages in examples of the present disclosure.

FIGS. 3A, 3B, 3C, 3D, 3E, 3F, 3G, 3H, 3I, 3J, 3K, 3L, and 3M show the cross sections of the corresponding steps of the process of FIG. 2 in examples of the present disclosure.

### DETAILED DESCRIPTION OF THE INVENTION

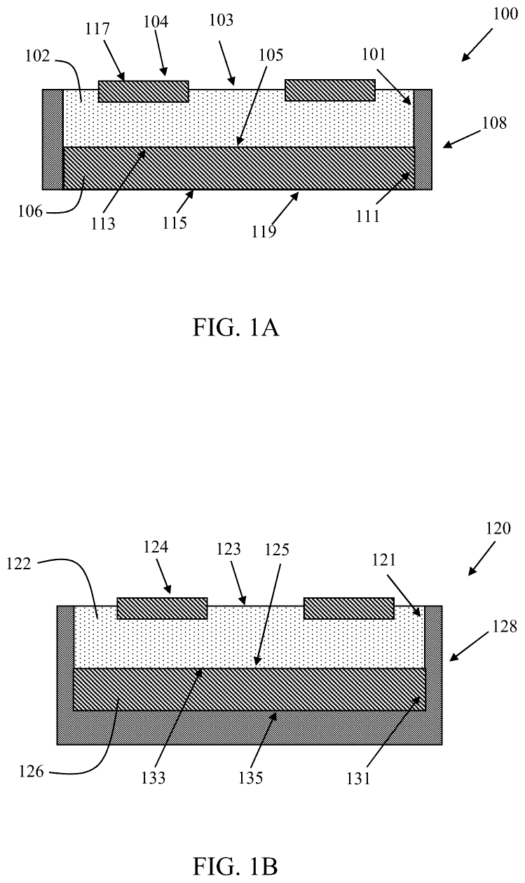

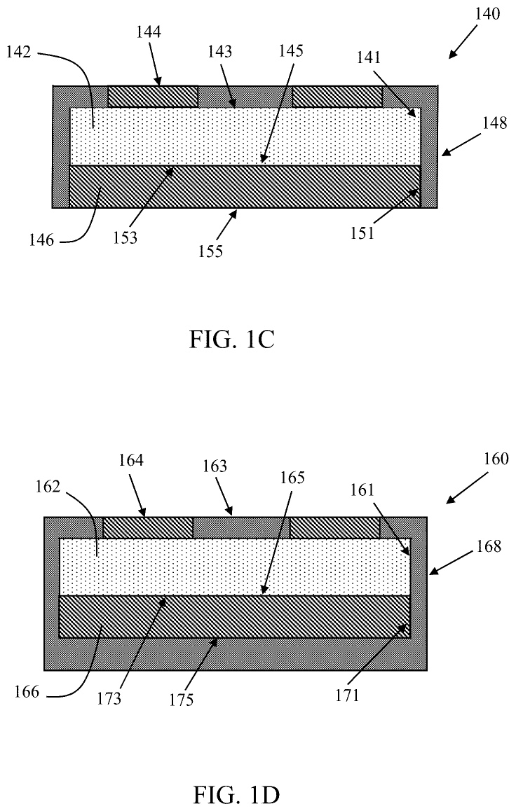

FIG. 1A shows a cross-sectional view of a semiconductor package 100 in examples of the present disclosure. The semiconductor package 100 comprises a semiconductor substrate 102, a plurality of contact pads 104, a plated metal layer 106, and a molding encapsulation 108. The semiconductor substrate 102 comprises a plurality of side surfaces 101, a front surface 103 and a back surface 105 opposite the front surface 103 of the semiconductor substrate 102. The plurality of contact pads 104 are attached to the front surface 103 of the semiconductor substrate 102. The plated metal layer 106 comprises a plurality of side surfaces 111, a front surface 113, and a back surface 115 opposite the front surface 113 of the plated metal layer 106. The front surface 113 of the plated metal layer 106 is directly attached to the back surface 105 of the semiconductor substrate 102. The molding encapsulation 108 directly contacts an entirety of each side surface of the plurality of side surfaces 101 of the semiconductor substrate 102, and an entirety of each side surface of the plurality of side surfaces 111 of the plated metal layer 106.

In examples of the present disclosure, a thickness of the semiconductor substrate 102 is in a range from 150 microns to 200 microns. A thickness of the plated metal layer 106 is in a range from 15 microns to 35 microns.

In examples of the present disclosure, the semiconductor substrate 102 is made of silicon. the plurality of contact pads 104 comprise nickel and gold. The plated metal layer 106 comprises copper or silver.

In examples of the present disclosure, the semiconductor package 100 is a double diffused metal oxide semiconductor field effect transistor (DMOSFET). The DMOSFET comprises: a source electrode 117 at a front surface of the DMOSFET; and a drain electrode at a back surface 119 of the DMOSFET.

FIG. 1B shows a cross-sectional view of a semiconductor package 120 in examples of the present disclosure. The semiconductor package 120 comprises a semiconductor substrate 122, a plurality of contact pads 124, a plated metal layer 126, and a molding encapsulation 128. The semiconductor substrate 122 comprises a plurality of side surfaces 121, a front surface 123 and a back surface 125 opposite the front surface 123 of the semiconductor substrate 122. The plurality of contact pads 124 are attached to the front surface 123 of the semiconductor substrate 122. The plated metal layer 126 comprises a plurality of side surfaces 131, a front surface 133, and a back surface 135 opposite the front surface 133 of the plated metal layer 126. The front surface 133 of the plated metal layer 126 is directly attached to the back surface 125 of the semiconductor substrate 122. The molding encapsulation 128 directly contacts an entirety of each side surface of the plurality of side surfaces 121 of the semiconductor substrate 122, and an entirety of each side surface of the plurality of side surfaces 131 of the plated metal layer 126. The molding encapsulation 128 further directly contacts an entirety of the back surface 135 of the plated metal layer 126.

FIG. 1C shows a cross-sectional view of a semiconductor package 140 in examples of the present disclosure. The semiconductor package 140 comprises a semiconductor substrate 142, a plurality of contact pads 144, a plated metal layer 146, and a molding encapsulation 148. The semiconductor substrate 142 comprises a plurality of side surfaces 141, a front surface 143 and a back surface 145 opposite the front surface 143 of the semiconductor substrate 142. The plurality of contact pads 144 are attached to the front surface 143 of the semiconductor substrate 142. The plated metal layer 146 comprises a plurality of side surfaces 151, a front surface 153, and a back surface 155 opposite the front surface 153 of the plated metal layer 146. The front surface 153 of the plated metal layer 146 is directly attached to the back surface 145 of the semiconductor substrate 142. The molding encapsulation 148 directly contacts an entirety of each side surface of the plurality of side surfaces 141 of the semiconductor substrate 142, and an entirety of each side surface of the plurality of side surfaces 151 of the plated metal layer 146. The molding encapsulation 148 further directly contacts the front surface 143 of the semiconductor substrate 142. A plurality of front surfaces of the plurality of contact pads 144 are exposed from the molding encapsulation 148.

FIG. 1D shows a cross-sectional view of a semiconductor package 160 in examples of the present disclosure. The semiconductor package 160 comprises a semiconductor substrate 162, a plurality of contact pads 164, a plated metal layer 166, and a molding encapsulation 168. The semiconductor substrate 162 comprises a plurality of side surfaces 161, a front surface 163 and a back surface 165 opposite the front surface 163 of the semiconductor substrate 162. The plurality of contact pads 164 are attached to the front surface 163 of the semiconductor substrate 162. The plated metal layer 166 comprises a plurality of side surfaces 171, a front surface 173, and a back surface 175 opposite the front surface 163 of the plated metal layer 166. The front surface 173 of the plated metal layer 166 is directly attached to the back surface 165 of the semiconductor substrate 162. The molding encapsulation 168 directly contacts an entirety of each side surface of the plurality of side surfaces 161 of the semiconductor substrate 162, and an entirety of each side surface of the plurality of side surfaces 171 of the plated metal layer 166. The molding encapsulation 168 further directly contacts an entirety of the back surface 175 of the plated metal layer 166. The molding encapsulation 168 still further directly contacts the front surface 163 of the semiconductor substrate 162. A plurality of front surfaces of the plurality of contact pads 164 are exposed from the molding encapsulation 168.

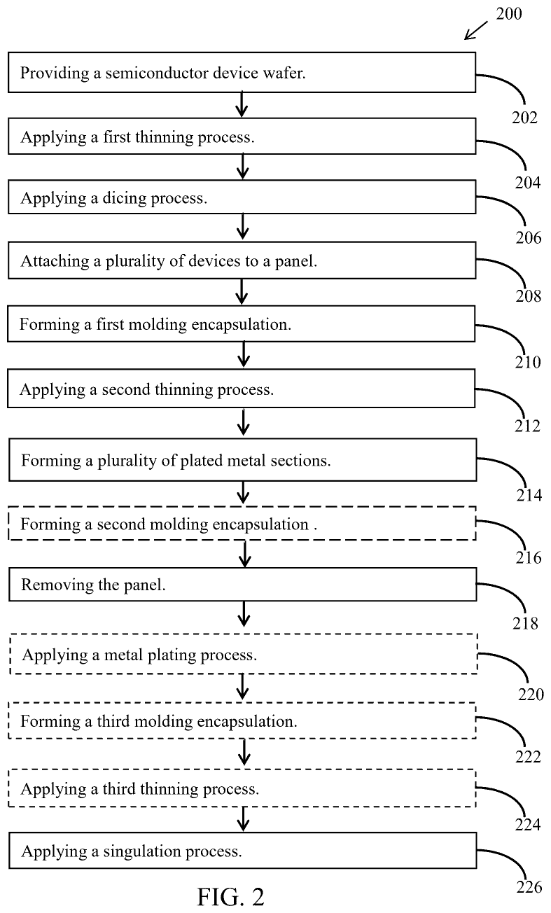

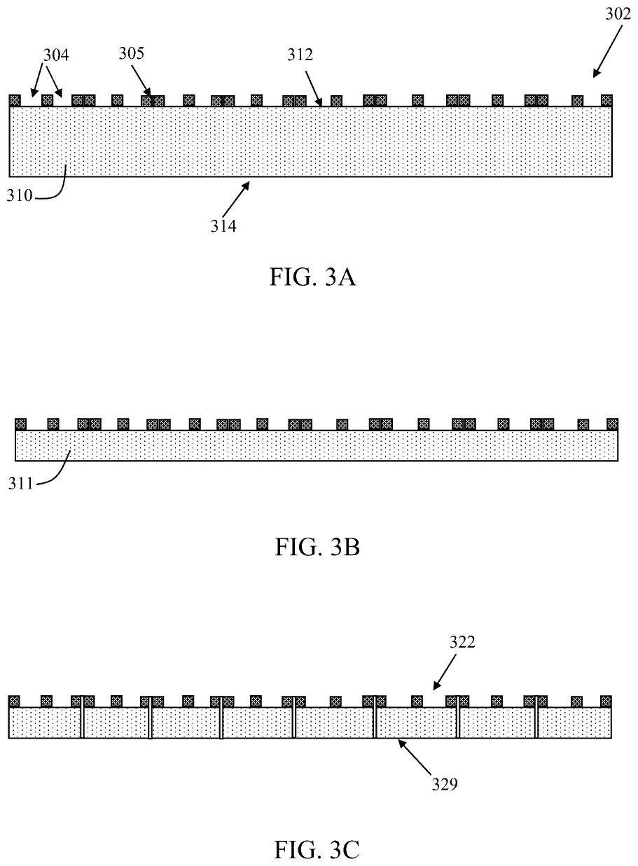

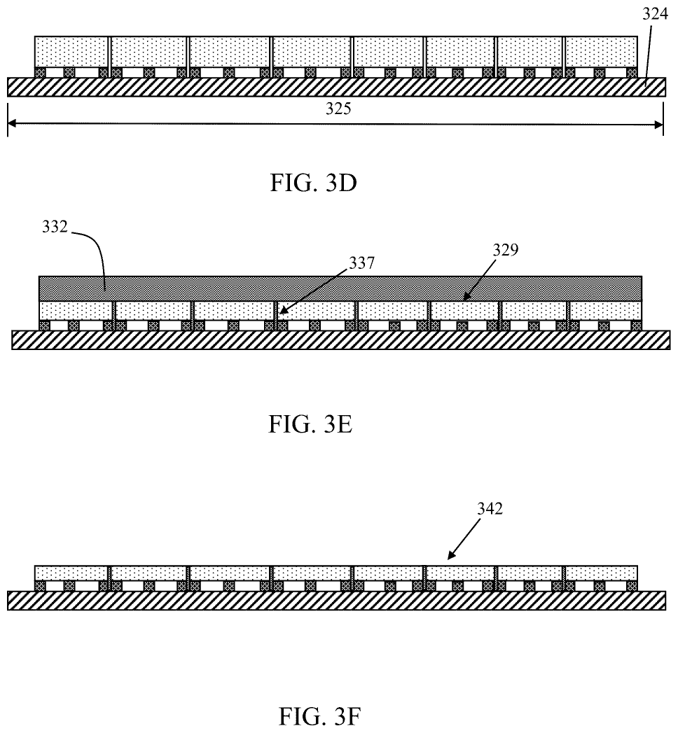

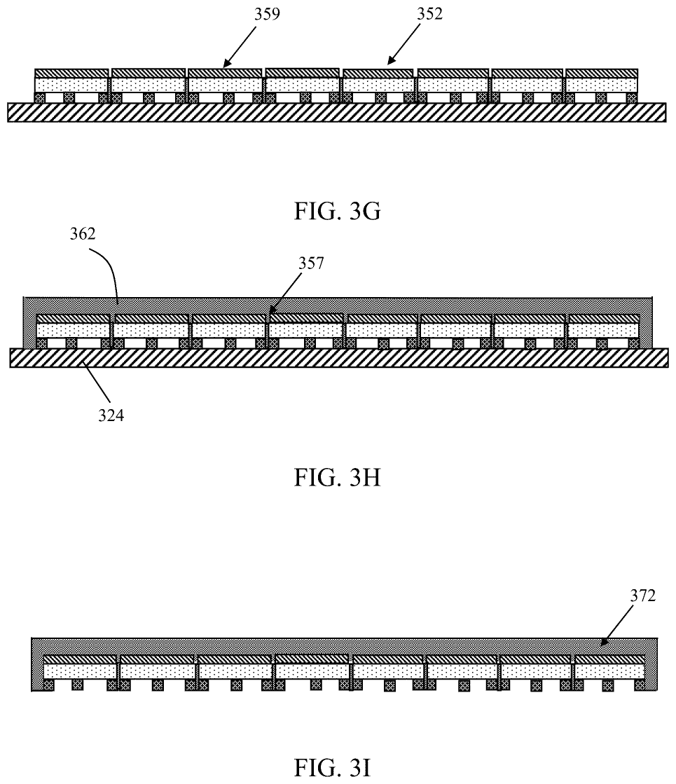

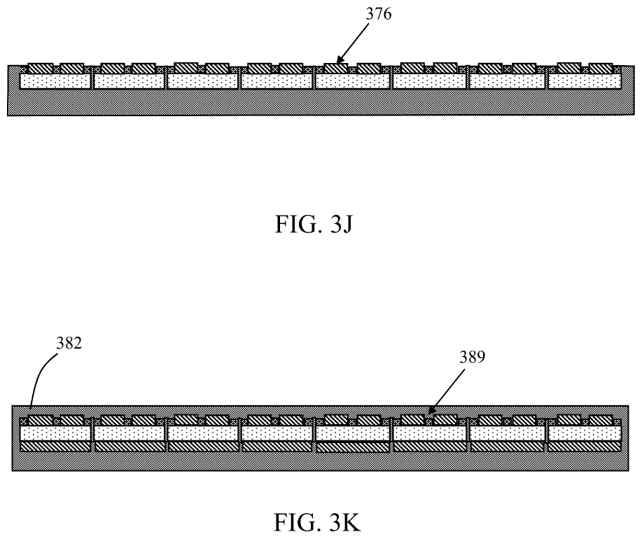

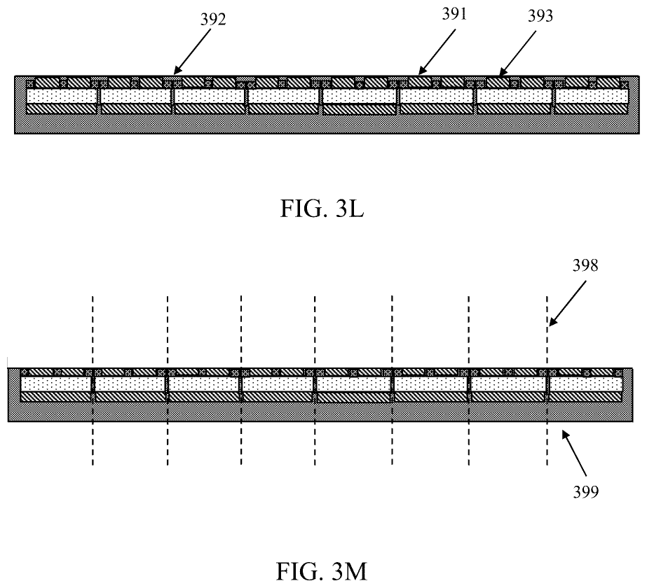

FIG. 2 is a flowchart of a process 200 to develop a plurality of semiconductor packages in examples of the present disclosure. FIGS. 3A, 3B, 3C, 3D, 3E, 3F, 3G, 3H, 3I, 3J, 3K, 3L, and 3M show the cross sections of the corresponding steps of the process 200 of FIG. 2 in examples of the present disclosure. The process 200 may start from block 202.

In block 202, referring now to FIG. 3A, a device wafer 302 is provided. The device wafer 302 comprises a semiconductor substrate 310 comprising a plurality of semiconductor devices formed thereon. The semiconductor substrate 310 has a front surface 312 and a back surface 314 opposite the front surface 312 of the semiconductor substrate 310. A plurality of contact pads 304 are attached to the front surface 312 of the semiconductor substrate 310 and exposed through a passivation layer 305. In examples of the present disclosure, each of the semiconductor device may comprise a first DMOSFET and a second DMOSFET formed as common drain with each of the plurality of contact pads 304 comprise aluminum source and gate electrodes of the first DMOSFET and the second DMOSFET. Block 202 may be followed by block 204.

In block 204, referring now to FIG. 3B, a first thinning process is applied over the back surface 314 of the semiconductor substrate 310 so as to formed a thinned semiconductor substrate 311. In examples of the present disclosure, a thickness of the thinned semiconductor substrate 311 is in a range from 150 microns to 200 microns. The thinning process may include back side grinding and back side etching. Block 204 may be followed by block 206.

In block 206, referring now to FIG. 3C, a dicing process is applied so as to separate a plurality of devices 322. The plurality of devices 322 comprises a plurality of back surfaces 329. Block 206 may be followed by block 208.

In block 208, referring now to FIG. 3D, the plurality of devices 322 are flipped and attached to a panel 324. A length 325 of the panel 324 is longer than a sum of a respective length of each device of the plurality of devices 322. Block 208 may be followed by block 210.

In block 210, referring now to FIG. 3E, a first molding encapsulation 332 is formed on a plurality of back surfaces 329 of the plurality of devices 322 and in a plurality of gaps 337 between the plurality of devices 322. Block 210 may be followed by block 212.

In block 212, referring now to FIG. 3F, a second thinning process is applied so as to remove a majority of the first molding encapsulation 332 and to further reduce the semiconductor substrate forming a plurality of thinned, connected devices 342. A thickness of the plurality of thinned, connected devices 342 is in a range from 15 microns to 35 microns. The plurality of the devices 342 are connected by the remaining material of molding encapsulation 332 filling the gaps 337 between adjacent devices 342. Block 212 may be followed by block 214.

In block 214, referring now to FIG. 3G, a plurality of plated metal sections 352 are formed on back surfaces of the plurality of thinned, connected devices 342. Preferably, a seed layer of conductive material comprising Ti/Cu is deposited by sputtering onto the entire flat back surface of the plurality of thinned, connected devices 342. A photoresist layer is applied onto the seed layer followed by masking process to exposed areas of the individual back surface of the plurality of thinned, connected devices 342. An electrode plating process is carried out to plate a metal section 352 from 15 μm to 35 μm in thickness on each of the plurality of thinned, connected devices 342. The remaining photoresists is then removed and so is the exposed seed layer material. Each of the plurality of plated metal sections 352 covers substantially an entire back surface of a corresponding connected device 342. In examples of the present disclosure, the plurality of plated metal sections 352 comprise copper or silver. The plurality of plated metal sections 352 comprise a plurality of back surfaces 359. The plurality of plated metal sections 352 becomes the plated metal layer 106 of FIG. 1A, the plated metal layer 126 of FIG. 1B, the plated metal layer 146 of FIG. 1C, and the plated metal layer 166 of FIG. 1D. Block 214 may be followed by optional block 216 or block 218.

In optional block 216 (shown in dashed lines), referring now to FIG. 3H, a second molding encapsulation 362 is formed on the plurality of back surfaces 359 of the plurality of plated metal sections 352 and in a plurality of gaps 357 between the plurality of plated metal sections 352. If the second molding encapsulation 362 formed on the plurality of back surfaces 359 of the plurality of plated metal sections 352 is removed to expose the back surface 359 of the plurality of the metal sections 352, the semiconductor package 100 of FIG. 1A or the semiconductor package 140 of FIG. 1C will be formed. If the second molding encapsulation 362 formed on the plurality of back surfaces 359 of the plurality of plated metal sections 352 is not removed, a portion of the second molding encapsulation 362 of FIG. 3H becomes the bottom portion of the molding encapsulation 128 of FIG. 1B or the bottom portion of the molding encapsulation 168 of FIG. 1D. Optional block 216 may be followed by block 218.

In block 218, referring now to FIG. 3I, the panel 324 of FIG. 3H is removed so as to form a processed wafer 372. Block 218 may be followed by optional block 220, optional block 222, optional block 224, or block 226.

In block 220 (shown in dashed lines), referring now to FIG. 3J, after flipping the processed wafer 372, a metal plating process is applied so as to form a plurality of metal sections 376 on top of the plurality of aluminum contact pads 304. As an option, an electrodeless plating process is carried out to form Au/Ni plated layer with a thickness up to 5 um on top of each aluminum electrodes. The process then skips optional block 222 and optional block 224 directly goes to block 226. Alternatively, the electrodeless plating process may be carried out before the block 204.

The metal sections 376 may also be formed by electrode plating process. Preferably, a seed layer of conductive material comprising Ti/Cu is deposited by sputtering onto the front surface of the processed wafer 372. A photoresist layer is applied onto the seed layer followed by masking process to exposed areas of each individual contact pad 304. An electrode plating process is carried out to plate a metal section 376 from 15 um to 35 um in thickness on each of the plurality of contact pads 304. The remaining photoresists is then removed and so is the exposed seed layer material. The metal sections 376 may comprise copper or silver. Optional block 220 may be followed by optional block 222, optional block 224, or block 226.

In optional block 222 (shown in dashed lines), referring now to FIG. 3K, a third molding encapsulation 382 is formed. The third molding encapsulation 382 is on top of the plurality of metal sections 376 and filled in the plurality of gaps 389 in between the plurality of metal sections 376. If optional block 222 is skipped, the semiconductor package 100 of FIG. 1A or the semiconductor package 120 of FIG. 1B will be formed. If optional block 222 is not skipped, a portion (after the third thinning process of optional block 224) of the third molding encapsulation 382 of FIG. 3K becomes the top portion of the molding encapsulation 148 of FIG. 1C or the top portion of the molding encapsulation 168 of FIG. 1D. Optional block 222 may be followed by optional block 224.

In optional block 224 (shown in dashed lines), referring now to FIG. 3L, a third thinning process is applied thereby thinning the third molding encapsulation 382 and the plurality of metal sections 376 so as to expose a plurality of surfaces 391 of a plurality of thinned metal sections 393 from the remaining third molding encapsulation 392. Optional block 224 may be followed by block 226.

In block 226, a singulation process, along the plurality of scribe lines 398, is provided to cut through the wafer so that to form a plurality of semiconductor packages 399. In examples of the present disclosure, each of the plurality of semiconductor packages 399 is a common drain dual DMOSFET. The common drain dual DMOSFET comprises two source electrodes and two gate electrodes at a front surface; and a drain electrode at a back surface. The first molding encapsulation 332 of FIG. 3E directly contacts an entirety of each side surface of a plurality of side surfaces of each package of the plurality of packages 399. The second molding encapsulation 362 of FIG. 3H directly contacts an entirety of each side surface of a plurality of side surfaces of each plated metal section of the plurality of plated metal sections 352.

Those of ordinary skill in the art may recognize that modifications of the embodiments disclosed herein are possible. For example, a total number of the plurality of contact pads 104 may vary. Other modifications may occur to those of ordinary skill in this art, and all such modifications are deemed to fall within the purview of the present invention, as defined by the claims.

1. A semiconductor package comprising:
a semiconductor substrate comprising:
a plurality of side surfaces;
a front surface; and
a back surface opposite the front surface of the semiconductor substrate;
a plurality of contact pads attached to the front surface of the semiconductor substrate;
a plated metal layer comprising:
a plurality of side surfaces;
a front surface; and
a back surface opposite the front surface of the plated metal layer,
the front surface of the plated metal layer being directly attached to the back surface of the semiconductor substrate; and
a molding encapsulation directly contacting an entirety of each side surface of the plurality of side surfaces of the semiconductor substrate, and an entirety of each side surface of the plurality of side surfaces of the plated metal layer.

2. The semiconductor package of claim 1, wherein a thickness of the semiconductor substrate is in a range from 15 microns to 35 microns; and
wherein a thickness of the plated metal layer is in a range from 15 microns to 35 microns.

3. The semiconductor package of claim 1, wherein the plurality of contact pads comprise nickel and gold.

4. The semiconductor package of claim 1, wherein the plurality of contact pads comprise copper or silver.

5. The semiconductor package of claim 1, wherein the plated metal layer comprises copper or silver.

6. The semiconductor package of claim 1, wherein the molding encapsulation further directly contacts an entirety of the back surface of the plated metal layer.

7. The semiconductor package of claim 1, wherein the molding encapsulation further directly contacts the front surface of the semiconductor substrate; and
wherein a plurality of front surfaces of the plurality of contact pads are exposed from the molding encapsulation.

8. The semiconductor package of claim 1, wherein the molding encapsulation further directly contacts an entirety of the back surface of the plated metal layer;
wherein the molding encapsulation further directly contacts the front surface of the semiconductor substrate; and
wherein a plurality of front surfaces of the plurality of contact pads are exposed from the molding encapsulation.

9. The semiconductor package of claim 1, wherein the semiconductor package is a common drain dual double diffused metal oxide semiconductor field effect transistor (DMOSFET).

10. The semiconductor package of claim 9, wherein the common drain dual DMOSFET comprises:
two source electrodes at a front surface of the DMOSFET; and
a common drain electrode at a back surface of the DMOSFET.

11. A method for fabricating a plurality of semiconductor packages, the method comprising the steps of:
providing a device wafer comprising
a semiconductor substrate having a front surface and a back surface opposite the front surface of the semiconductor substrate; and
a plurality of contact pads attached to the front surface of the semiconductor substrate;
applying a first thinning process over the back surface of the semiconductor substrate so as to form a thinned semiconductor substrate having a first predetermined thickness;
applying a dicing process separating a plurality of devices;
attaching the plurality of devices to a panel;
forming a first molding encapsulation on a plurality of back surfaces of the plurality of devices and in a plurality of gaps between the plurality of devices;
applying a second thinning process removing a majority of the first molding encapsulation and further reducing thickness of the plurality of devices forming a plurality of thinned, connected devices having a second predetermined thickness;
forming a plurality of plated metal sections on back surfaces of the plurality of thinned, connected devices;
forming a second molding encapsulation on a plurality of back surfaces of the plurality of plated metal sections and in a plurality of gaps between the plurality of plated metal sections;
removing the panel; and
applying a singulation process forming the plurality of semiconductor packages.

12. The method of claim 11, wherein a thickness of the first predetermined thickness is in a range from 150 microns to 200 microns; and
wherein a thickness of the second predetermined thickness is in a range from 15 microns to 35 microns.

13. The method of claim 11, further comprising, after the step of removing the panel,
applying a metal plating process forming a plurality of metal sections on top of the plurality of contact pads;
forming a third molding encapsulation; and
applying a third thinning process thinning the third molding encapsulation and the plurality of metal sections so as to expose a plurality of surfaces of a plurality of thinned metal sections.

14. The method of claim 11, wherein the plurality of plated metal sections are formed by electrode plating process.

15. The method of claim 11, wherein the plurality of contact pads comprise nickel and gold.

16. The method of claim 11, wherein the plurality of plated metal sections comprise copper or silver.

17. The method of claim 11, wherein each of the plurality of semiconductor packages is a double diffused metal oxide semiconductor field effect transistor (DMOSFET).

18. The method of claim 17, wherein the DMOSFET comprises:
a source electrode at a front surface of the DMOSFET; and
a drain electrode at a back surface of the DMOSFET.

19. The method of claim 11, wherein the first molding encapsulation directly contacts an entirety of each side surface of a plurality of side surfaces of each device of the plurality of devices; and
wherein the second molding encapsulation directly contacts an entirety of each side surface of a plurality of side surfaces of each plated metal section of the plurality of plated metal sections.
